(19) United States
(12) Patent Application Publication
(10) Pub. No.: US 2026/0143607 A1
(43) Pub. Date: May 21, 2026

(54) SMOKE DETECTOR COVER APPARATUS

(71) Applicants: Brenda Kay Sandmann, Fairfax, MN (US); Jonathan Dennis Sandmann, Fairfax, MN (US)

(72) Inventors: Brenda Kay Sandmann, Fairfax, MN (US); Jonathan Dennis Sandmann, Fairfax, MN (US)

(21) Appl. No.: 19/381,485

(22) Filed: Nov. 6, 2025

Related U.S. Application Data
(60) Provisional application No. 63/722,414, filed on Nov. 19, 2024.

(51) Int. Cl. H05K 5/02; G08B 17/10; H05K 5/03

(52) U.S. Cl. CPC H05K 5/0243; G08B 17/10; H05K 5/0213; H05K 5/0221; H05K 5/03

(57) ABSTRACT

A smoke detector cover apparatus having a cover, a screen, and a base is provided. The cover includes ornamental indica, and a side wall having slats to promote the flow of air and smoke particles through a smoke detector mechanism being covered. The cover is securably, and removably, affixed to the base using lock tabs disposed on the side wall and lock tab slats disposed in the base in a twist-to-lock configuration. To use the cover of the present invention a user affixes the base to a structure using fasteners, optionally affixes the screen to the cover, and places each lock tab into a lock tab slot and twists such that a frictional interface is formed, securing the cover to the base.

### CROSS-REFERENCE TO RELATED APPLICATIONS

This application claims benefit to Provisional Application No. 63/722,414, filed Nov. 19, 2024, the contents of which are herein incorporated by reference.

### BACKGROUND OF THE INVENTION

### Field of Endeavor

The present invention relates to smoke detector covers, and more particularly, to a smoke detector cover for mounting over a smoke alarm while allowing smoke to pass through for effective smoke detection.

### Background of Related Art

Smoke detectors are critical life-safety devices designed to provide early warning of fire, giving occupants time to escape before conditions become deadly. They reduce the risk of dying in a home fire by about 50%. Current smoke detector solutions are either: Ionization detectors that utilize radioactive material to ionize air to detect smoke particles, Photoelectric detectors that utilize a light beam and sensor to detect smoke particles, or a combination detector that utilizes both mechanisms to detect smoke. These current solution require air and smoke particles to travel freely through the mechanism for effective and efficient detection. These smoke detectors are unsightly, and users wish to cover their smoke detectors, but do not wish to impair their functionality.

As can be seen, there is a need for a smoke detector cover that fits over a smoke detector without impair the functionality associated therewith.

### SUMMARY OF THE INVENTION

A smoke detector cover apparatus having a cover, a screen, and a base is provided. In embodiments, the cover includes a face having a plurality of surface, and one or more ornamental indica thereon, and at least one side wall extending therefrom and having a plurality of slats disposed therethrough. The ornamental indicia and slats, as bores, or apertures, allow for air flow, and smoke particle flow through a smoke detection mechanism being cover, for proper operation. The cover includes a plurality of tabs extending therefrom for affixing the screen thereto. In embodiments, the screen is a mesh screen for visually obscuring the smoke detection mechanism while allowing proper air flow. In embodiments, the base is securable to a structure and removably affixes the cover thereto.

A method of using the smoke detector cover apparatus is provided. The method includes affixing the base around a smoke detection apparatus and to a structure, such as a wall, or ceiling. Once the base is affixed, optionally, the screen is affixed to the cover by press fitting the screen onto one or more of the plurality of tabs. A portion of the cover is then inserted into a portion of the base, and secured using a twist-to-lock mechanism.

### BRIEF DESCRIPTION OF THE DRAWINGS

FIG. 1 is a perspective view of a Smoke Detector Cover, according to aspects of the present invention;

FIG. 2 is a side view of a Smoke Detector Cover, according to aspects of the present invention;

FIG. 3 is an exploded view of a Smoke Detector Cover and Screen, according to aspects of the present invention;

FIG. 4 is a perspective view of a Smoke Detector Cover Base, according to aspects of the present invention;

FIG. 5 is an exploded view of a Smoke Detector Cover and Base, according to aspects of the present invention;

FIG. 6 is a first top view of a Smoke Detector Cover showing installation on the Base, according to aspects of the present invention; and

FIG. 7 is a second top view of a Smoke Detector Cover showing installation on the Base, according to aspects of the present invention.

### DETAILED DESCRIPTION OF THE INVENTION

The following detailed description is of the best currently contemplated modes of carrying out exemplary embodiments of the invention. The description is not to be taken in a limiting sense but is made merely for the purpose of illustrating the general principles of the invention, since the scope of the invention is best defined by the appended claims.

As stated above, proper operation of smoke detectors is critical to the health and safety of users who rely on them. However, smoke detectors are unsightly and users wish to obscure them without impairing the functionality associated therewith.

Broadly, an embodiment of the present invention is a smoke detector cover having a base, a mesh, and a cover for covering a smoke detector without impairing the flow of air, or smoke, thereby allowing proper functionality of the smoke detector apparatus therein.

Broadly, embodiments of the present invention are made of durable materials, such as plastics, metals, etc. Additionally, embodiments of the present invention are manufactured through one or more manufacturing techniques such as: additive manufacturing techniques, such as injection molding, three-dimensional printings, etc., or subtractive manufacturing techniques, such as machining, milling, etc. Additionally, embodiments of the present invention are customizable in dimension.

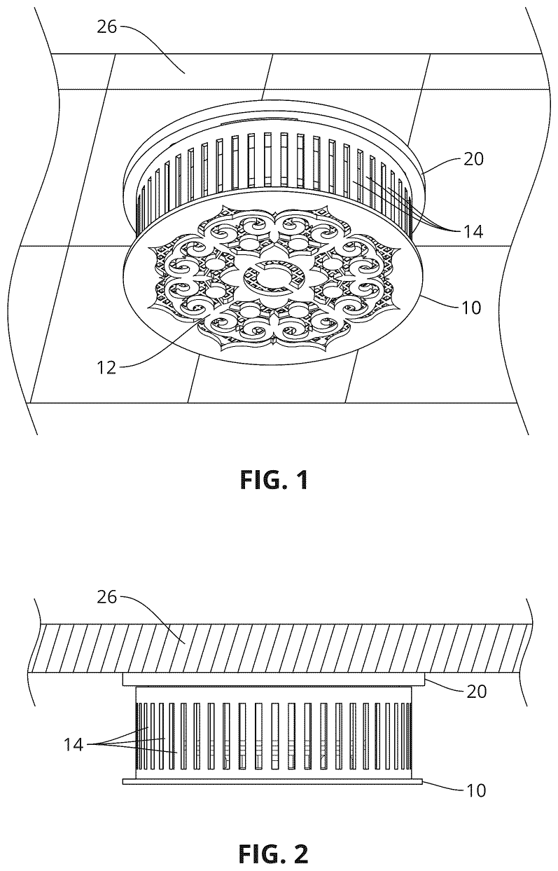

Referring now to the Figures, FIGS. 1-7 illustrate aspects of a smoke detector cover, according to aspects of the present invention. Briefly, and described in more detail below, the smoke detector cover of the present invention includes components, such as a cover 10, a screen 18, and a base 20. The base 20 is fastened to a structure 26, such as a wall, or ceiling, and cover 10 is removably affixable to the base 20, as illustrated in FIG. 1-2. Cover 10 has a face 12 having ornamental indicia thereon, and a side wall extending from a surface of face 12 having a plurality of slats 14 disposed therethrough. In embodiments, both the ornamental design and plurality of slats 14, include apertures, or bores, allow air and smoke particles to flow into a smoke detector mechanism, thereby allowing operation thereof.

Referring more specifically to cover 10, face 12 of cover 10 includes a plurality of surfaces such as an outer surface, an inner surface, and at least one side surface disposed between the outer surface and the inner surface. In embodiments, face 12 is shaped as a cylinder, but is not so limited, other shapes such as prisms, cuboid, etc., are equally contemplated. Ornamental indica are disposed in, or on, face 12 to provide a visual appeal for the apparatus. In embodiments, the ornamental indica are bores, or apertures, disposed from the outer surface to the inner surface, and are configured to allow air, and smoke particles, to flow from the environment to a smoke detector mechanism inside of cover 10. In an exemplary embodiment, face 12 is a cylinder of diameter approximately 5.7043 inches and has a height, defined as the distance between the outer and inner surfaces, or the thickness of the at least one side surface, of approximately 0.1000 inches.

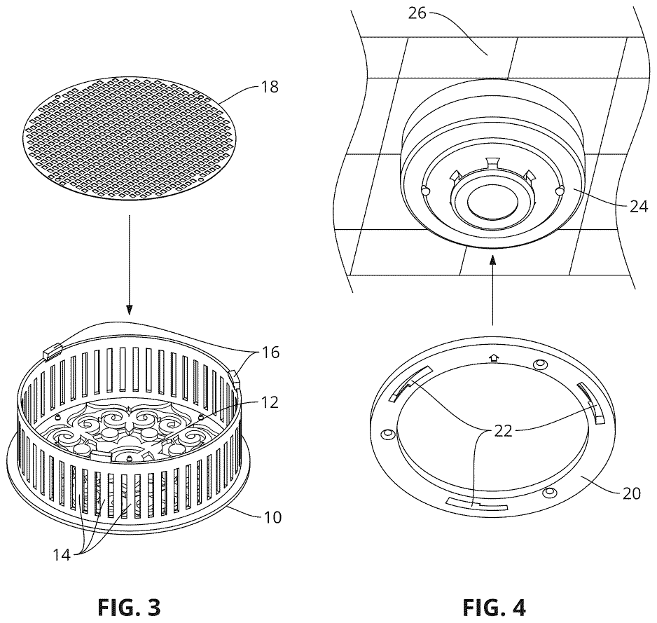

The side wall of cover 10 includes a plurality of surfaces such as an outer surface, an inner surface and at least one side surface disposed between the outer surface and the inner surface. Additionally, the side wall of cover 10 extends continuously from a surface of face 12, such as the inner surface of face 12, and creates a negative space that is dimensioned such that a smoke detector fits wholly therein without modification. In embodiments, the side wall is shaped as a cylindrical shell, or tube, but is not so limited, as any shape having a hollow inner diameter is equally contemplated. The side wall of cover 10 includes a plurality of slats 14 disposed thereon. In embodiments, plurality of slats 14 are bores, or apertures, disposed from the outer surface to the inner surface, and are configured to allow air, and smoke particles, to flow from the environment to a smoke detector mechanism inside of cover 10. The side wall cover includes a plurality of locking tabs 16 disposed on the at least one side surface, as illustrated in FIG. 3. Locking tabs 16 allow cover 10 to be removably, and securably, affixed to base 20, as described further hereinafter. In embodiments, locking tabs 16 each include a body and a notch, or shoulder, protruding from the body thereof. In an exemplary embodiment, the side wall, as a cylindrical shell, has a height of approximately 1.7500 inches, and each of the plurality of slats 14 have a length of approximately 0.1250 inches and a height of approximately 1.25 inches. In the exemplary embodiment, a total height of face 12 and the side wall is approximately 1.8500 inches. In the exemplary embodiment, the body of each locking tab 16 is approximately 0.1875 inches, with the notch being disposed approximately 0.750 inches from an end of each locking tab 16 that is affixed to the side wall.

A screen 18 is optionally provided and sits on the inner surface of face 12 when cover 10 is secured to base 20 as illustrated in FIG. 3. Screen 18 includes a plurality of bores, or apertures, thereon, which are configured to allow air, and smoke particles to flow from the environment to a smoke detection mechanism inside cover 10. In embodiments, screen 18 is dimensioned to fit within the negative space created by face 12 and the side wall of cover 10. In embodiments, screen 18 is a mesh screen, but is not so limited. In embodiments, screen 18 affixes to one or more tabs (unlabeled) disposed on the inner surface of face 12. In embodiments, the one or more tabs are dimensioned to fit within one of the plurality of bores, or apertures, of screen 18. In an exemplary embodiment, screen 18 is cylindrical in shape with an outer diameter of approximately 5.000 inches, and the plurality of bores, or apertures, include at least two differently dimensioned bores, or apertures. In the exemplary embodiment, a first of the plurality of bores is dimensioned to receive the one or more tabs on the inner surface of face 12, and have a diameter of approximately 0.1180 inches, while a second of the plurality of bores as spaced in a grid pattern while a longitudinal spacing of approximately 0.0600 inches and a latitudinal spacing of approximate 0.0650 inches. Additionally, the second of the plurality of bores have a length of approximately 0.1000 inches and a height of 0.1250 inches.

Base 20 includes a plurality of surfaces such as a bottom surface, a top surface, and at least two side surfaces disposed between the bottom surface and the top surface. In embodiments, base 20 is shaped as a cylindrical shell, or tube, but is not so limited, as any shape having a hollow inner diameter is equally contemplated. In embodiments, an inner side surface of the at least two side surfaces forms a hollow inner diameter, which is dimensioned to fit around a smoke detector 24, as illustrated in FIGS. 4-7. In an exemplary embodiment, base 20, as a cylindrical shell has an outer diameter of approximately 5.7500 inches and an inner diameter of approximately 4.5000 inches.

Base 20 includes a plurality of fastener holes, as bores or apertures, which each receive a fastener to secure base 20 to structure 26. In embodiments, a fastener is a screw, bolt, anchor, etc., but is not so limited. In an exemplary embodiment, the fastener holes have an inner diameter of approximately 0.1770 inches. Base 20 includes a plurality of lock tab slots 22, as bores or apertures, which each receive a lock tab 16 for securing cover 10 to base 20.

Referring more specifically to the plurality of lock tab slots 22, each of the plurality of lock tab slots 22 is an a bore, or aperture dimensioned to receive one of the plurality of lock tabs 16. In embodiments, each of the plurality of lock tab slots 22 includes a notch, or shoulder, extending from a surface, or a portion of a surface, thereof. In embodiments, each notch, or shoulder, extends, at least, along a part of a longitudinal portion of a surface thereof, as illustrated in FIGS. 4-7. In an exemplary embodiment, each of the plurality of lock tab slots 22 have a length of approximately 1.3289 inches, with each notch having a length of approximately 0.7500 inches.

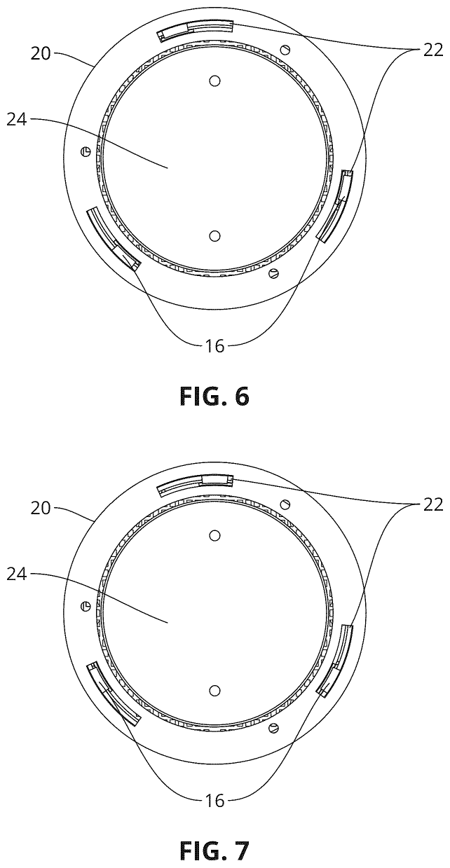

In use, each of the plurality of lock tabs 16 is disposed in a portion of one of the plurality of lock tab slots 22, not having the notch, and once disposed therein, cover 10 is twisted such that each notch of the plurality of lock tab slots 22 interfaces with the notch of the lock tab 16 disposed therein, as illustrated in FIGS. 6-7. In embodiments, friction between the notches of the lock tabs 16 and the notches of the lock tab slots 22 allows securable affixation of cover 10 to base 20.

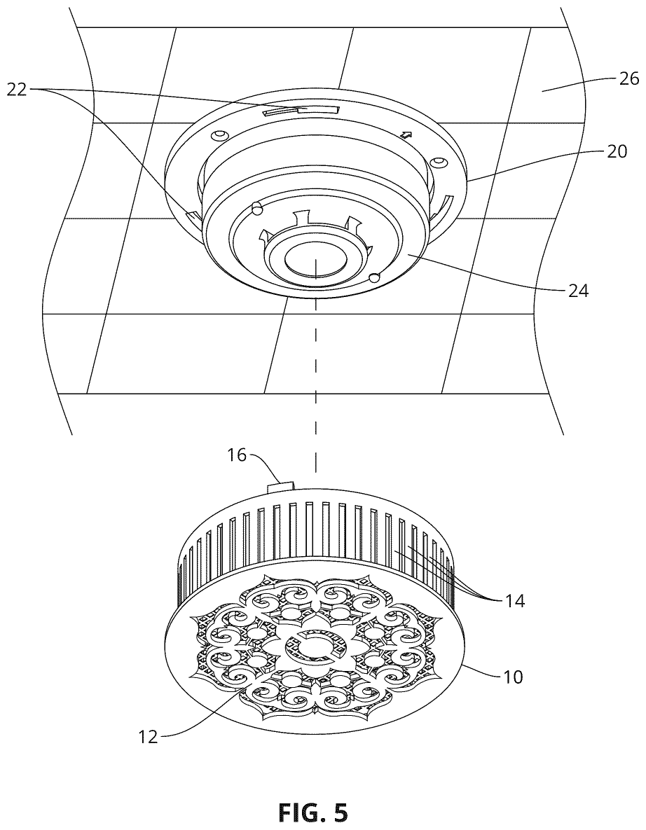

More specifically, to use the smoke detector cover apparatus of the present invention, a user affixes base 20 to structure 26, and surrounding smoke detector 24, using fasteners disposed through each of the fastener holes (unlabled), as illustrated in FIGS. 1-2. Once base 20 is affixed to structure 26, the user, optionally, affixes screen 18 to cover 10, by press fitting one or more bores of screen 18 over the one or more tabs (unlabeled) protruding from the inner surface of face 12, as illustrated in FIG. 3. The user then inserts each of lock tabs 16 into one of lock tab slots 22, at a portion of lock tab lock 22 not having the notch, or shoulder, as illustrated in FIGS. 5-6. Once inserted, the user twists, in a first direction, such as clockwise, over 10 such that each notch of each lock tab 16 engages the corresponding notch, or shoulder, of the lock tab slot 22 it is disposed in, as illustrated in FIG. 7. In embodiments, frictional forces secure lock tabs 16 to lock tab slots 22. Additionally, to remove cover 10, the user twists cover 10 in a second direction, such as counter-clockwise. To remove the optional screen 18, the user pulls screen 18 until it is dislodged from the one or more tabs. Finally, to remove base 20, the user removes the fasteners securing base 20 to structure 26.

It should be understood, of course, that the foregoing relates to exemplary embodiments of the invention and that modifications may be made without departing from the spirit and scope of the invention as set forth in the following claims. It should be understood that dimension are provided for exemplary embodiments, but are not limiting, as the apparatus, and components of the apparatus of the present invention can be resize, or size, to fit a variety of smoke detectors.

What is claimed is:

1. A smoke detector cover apparatus, comprising:
a cover having a face and a continuous side wall extending from the face, wherein the continuous side wall has a plurality of slats;
a plurality of lock tabs extending from the continuous side wall; and
a base having a plurality of lock tab slots for securably receiving one of the plurality of lock tabs.

2. The smoke detector cover apparatus of claim 1, further comprising:
one or more tabs extending from the cover; and
a screen affixable to the one or more tabs.
